(19) United States
(12) Patent Application Publication
(10) Pub. No.: US 2024/0324130 A1
(43) Pub. Date: Sep. 26, 2024

(54) CURVED COVER UNIT ATTACHMENT/DETACHMENT APPARATUS AND METHOD

(71) Applicant: KORTEK CORPORATION, Incheon (KR)

(72) Inventors: Won Sub SHIN, Incheon (KR); Hong Jin JEON, Goyang-si, Gyeonggi-do (KR)

(21) Appl. No.: 18/579,899

(22) PCT Filed: Jul. 22, 2022
(86) PCT No.: PCT/KR2022/010789

§ 371 Date: Jan. 17, 2024

(30) Foreign Application Priority Data
Aug. 27, 2021 (KR) 10-2021-0113739

(51) Int. Cl. H05K 5/03; H05K 5/00; H05K 5/02

(52) U.S. Cl. CPC H05K 5/03; H05K 5/0208; H05K 5/0008

(57) ABSTRACT

A curved cover unit is provided having a curved cover member formed as a curved surface, a first bracket unit provided on the curved cover unit, a curved panel unit coupled to the first bracket unit, and a second bracket unit provided on the curved panel unit and coupled to at least one of the curved cover unit or the first bracket unit. Also disclosed is a curved cover unit attachment and detachment method having a first separation step of separating a first bracket unit and a curved panel unit; a second separation step of separating a second bracket unit and the curved cover unit; and a third separation step of separating the curved cover unit from the curved panel unit.

### CROSS-REFERENCE TO RELATED APPLICATIONS

This application claims priority to PCT Application No. PCT/KR2022/010789, having a filing date of Jul. 22, 2022, claiming priority to KR Application No. 10-2021-0113739, having a filing date of Aug. 27, 2021, the entire both contents of which are hereby incorporated by reference.

### FIELD OF TECHNOLOGY

The following relates to a curved cover unit attachment/detachment apparatus and method, and more specifically, to a curved cover unit attachment/detachment apparatus and method, capable of attaching and detaching a curved cover unit to a curved panel unit.

### BACKGROUND

With the advancement of information-oriented society, a demand for display devices for displaying images is increasing in various forms. In recent years, as screens of display devices become flat and larger, there is a problem in that a deviation between a viewing distance to a center of a screen and a viewing distance to regions on both sides of the screen increases. In order to maximize the immersion of a user watching an image while improving the viewing distance deviation, a curved display device where a flat screen is curved at a certain curvature has been suggested.

While the curved display device has the advantage of improving the viewing distance deviation, the curved display device has disadvantages that a manufacturing process is complicated and an assembly process is also unfavorable compared to a flat display device. That is, for the display device with a flat screen, it is easy to attach and detach a front panel or glass part, but for the curved display device, it is difficult to attach and detach because the curved display device has a curved shape, and damage to a curved glass, panel, or the like, which is a protective member, occurs in the process of the attachment and detachment.

The conventional technology is disclosed in Korean Utility Model Publication No. 20-1998-0019496 (published on Jul. 15, 1998).

### SUMMARY

An aspect relates to a curved cover unit attachment/detachment apparatus and method, capable of improving damage to a curved cover unit or a curved panel unit that may occur during an attachment and detachment process.

One aspect of embodiments of the present invention provide a curved cover unit attachment/detachment apparatus including a curved cover unit having a curved cover member formed as a curved surface, a first bracket unit provided on the curved cover unit, a curved panel unit coupled to the first bracket unit, and a second bracket unit provided on the curved panel unit and coupled to at least one of the curved cover unit or the first bracket unit.

The first bracket unit may include a first bracket member provided on the curved cover member and a first support member detachably installed on the first bracket member. Here, the first support member may include a first fixing portion that fixes at least one of the curved cover unit or the first bracket member and a first support portion detachably coupled to the curved panel unit. In addition, the apparatus may further include a free support unit provided on the first bracket member and a free support coupling unit which is provided on the curved panel unit and to which the free support unit is coupled. The free support unit may include a body portion provided on the first bracket member, a first extension portion extending from the body portion in a first direction away from the first bracket member, and a second extension portion extending from the first extension portion in a direction different from the first direction to be spaced apart from the body portion.

The second bracket unit may include a second support member coupled to at least one of the curved cover unit or the first bracket unit. The second support member may include a second support portion that detachably fixes at least one of the curved cover unit or the first bracket unit, and a second fixing portion fixedly coupled to the curved panel unit.

The first bracket unit may be fixed to the curved cover unit and separably coupled to the curved panel unit, and the second bracket unit may be separably coupled to the curved cover unit and fixed to the curved panel unit.

Another aspect of embodiments of the present invention provide a curved cover unit attachment and detachment method including a first separation step of separating a first bracket unit and a curved panel unit, a second separation step of separating a second bracket unit and the curved cover unit, and a third separation step of separating the curved cover unit from the curved panel unit.

The first separation step may include separating the first bracket unit from the curved panel unit in a state of fixing the first bracket unit to the curved cover unit.

The second separation step may include separating the second bracket unit from the curved cover unit in a state of fixing the second bracket unit to the curved panel unit.

The third separation step may include separating the curved cover unit by moving the curved cover unit to one side of the curved panel unit.

In embodiments of the present invention, since a curved cover unit can be separated from a curved panel unit by separating only unit of a first bracket unit and a second bracket unit, it is possible to easily replace the curved cover unit.

In addition, in embodiments of the present invention, it is possible to prevent a curved cover member or the curved panel unit from being damaged during a replacement process.

In addition, in embodiments of the present invention, since the curved cover unit can be separated by disassembling only part of a device without disassembling the entire device, it is possible to easily perform an operation and allow even unskilled people to easily work.

In addition, in embodiments of the present invention, since a free support unit can be coupled to a free support coupling unit, it is possible to easily position the curved cover unit when coupling the curved cover unit to the curved panel unit, and since the free support unit and the free support coupling unit are not fastened by other fastening members, it is possible to easily separate the free support unit and the free support coupling unit when separating them.

### BRIEF DESCRIPTION

Some of the embodiments will be described in detail, with references to the following Figures, wherein like designations denote like members, wherein:

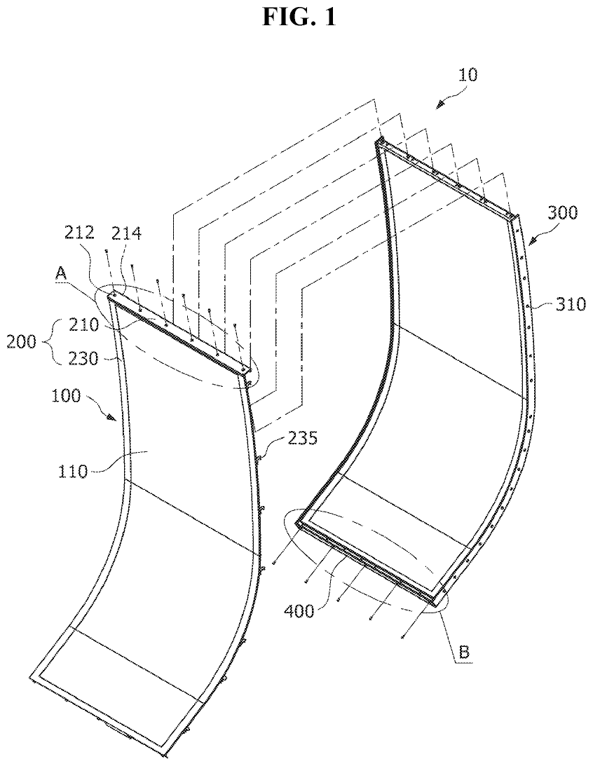

FIG. 1 is a perspective view illustrating a curved cover unit attachment/detachment apparatus according to an embodiment of the present invention;

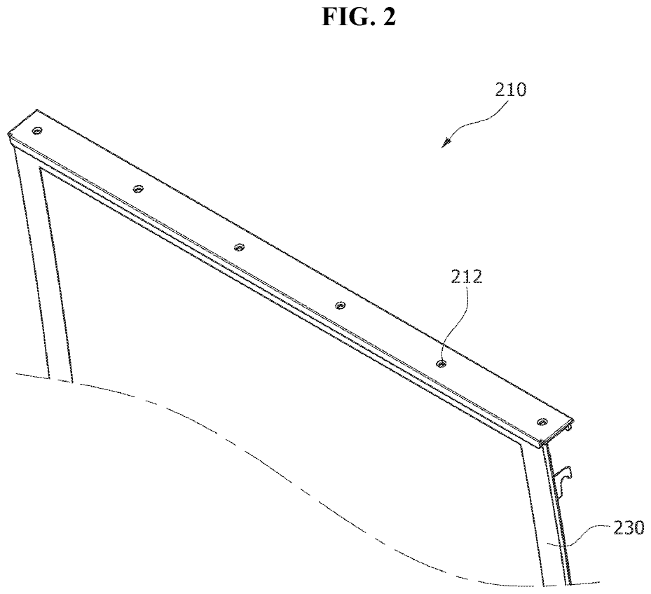

FIG. 2 is an enlarged view of part A of FIG. 1, which is a partial perspective view illustrating a state in which a first bracket member and a first support member of the curved cover unit attachment/detachment apparatus according to an embodiment of the present invention are coupled:

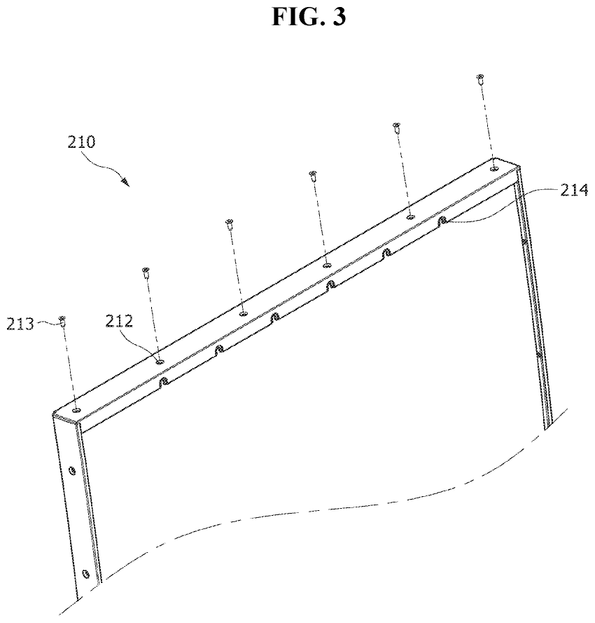

FIG. 3 is a partial rear perspective view illustrating the state in which the first bracket member and the first support member of the curved cover unit attachment/detachment apparatus according to an embodiment of the present invention are coupled:

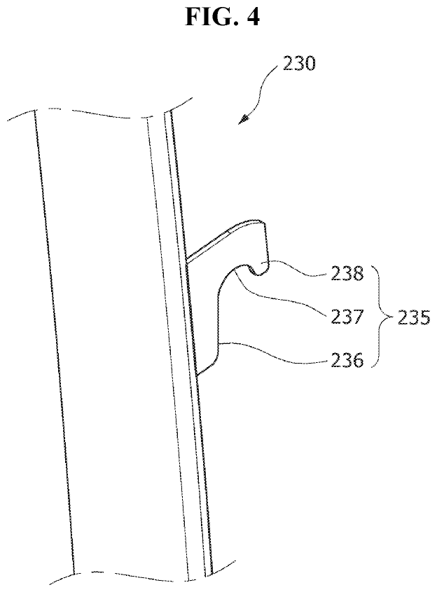

FIG. 4 is a view illustrating a free support unit of the curved cover unit attachment/detachment apparatus according to an embodiment of the present invention:

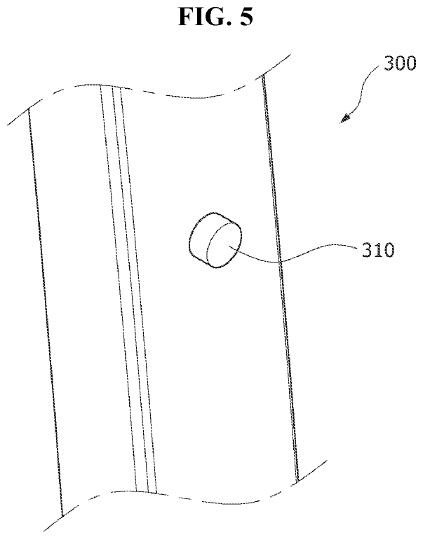

FIG. 5 is a view illustrating a free support coupling unit of the curved cover unit attachment/detachment apparatus according to an embodiment of the present invention:

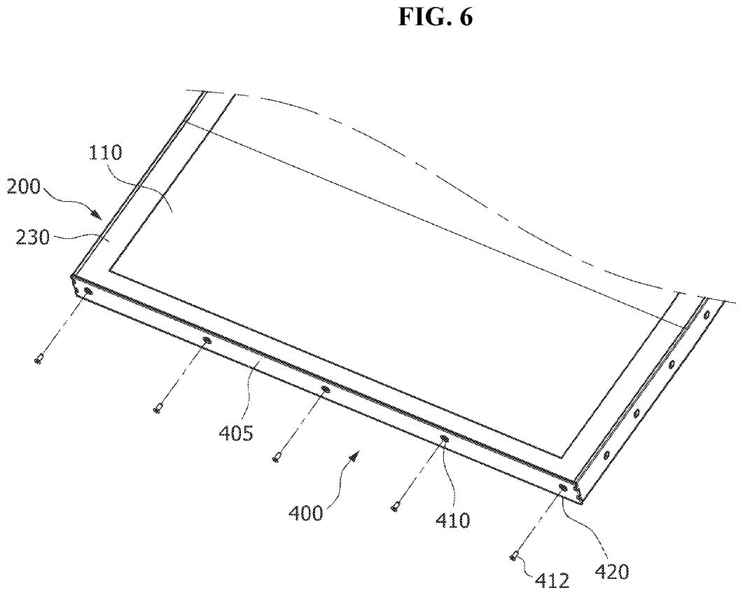

FIG. 6 is a partial perspective view illustrating part B of FIG. 1 in a state in which the curved cover unit attachment/detachment apparatus according to an embodiment of the present invention is coupled:

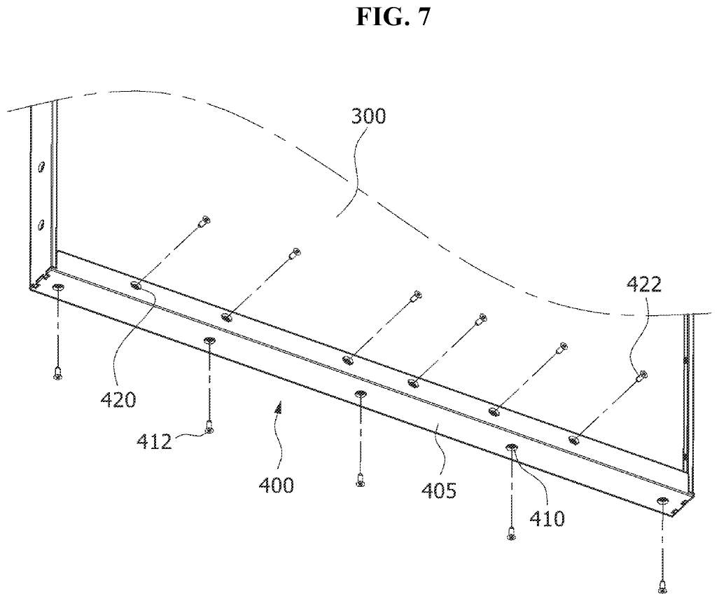

FIG. 7 is a rear perspective view of FIG. 6;

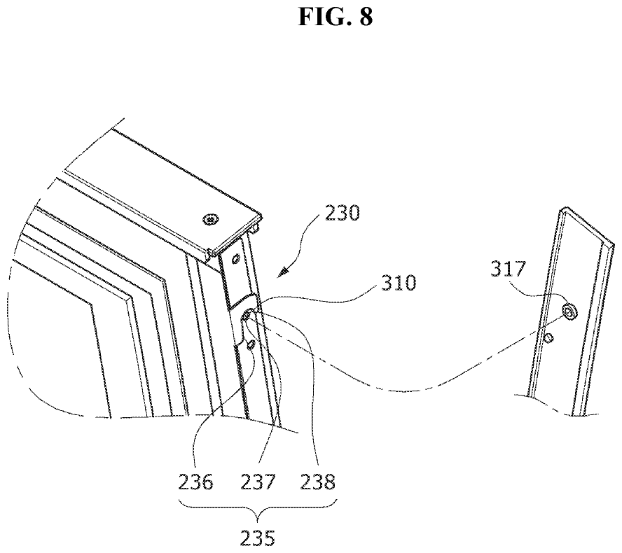

FIG. 8 is a view illustrating a free support unit and a free support coupling unit according to an embodiment of the present invention; and

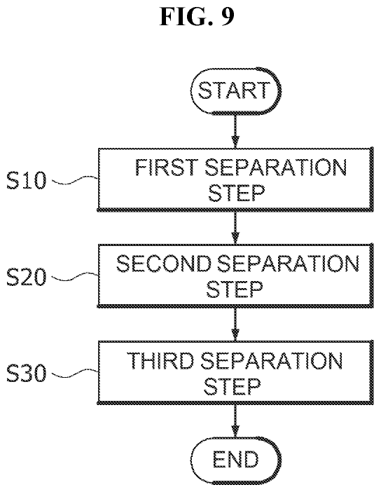

FIG. 9 is a flowchart showing a curved cover unit attachment and detachment method according to an embodiment of the present invention.

### DETAILED DESCRIPTION

Hereinafter, exemplary embodiments according to the present invention will be described in detail with reference to the accompanying drawings.

In the drawings, thicknesses of lines, dimensions of elements, and the like, may be exaggerated for clarity and convenience. Also, terms described below may be defined in consideration of functions in embodiments of the present invention, and may be changed depending on the customary practice or the intention of a user or operator. Thus, definitions of such terms should be determined based on the overall content of the present specification.

FIG. 1 is a perspective view illustrating a curved cover unit attachment/detachment apparatus according to an embodiment of the present invention.

Referring to FIG. 1, a curved cover unit attachment/detachment apparatus 10 according to an embodiment of the present invention includes a curved cover unit 100, a first bracket unit 200 provided on the curved cover unit 100, a curved panel unit 300 coupled to the first bracket unit 200, and a second bracket unit 400 provided on the curved panel unit 300 and coupled to at least one of the curved cover unit 100 or the first bracket unit 200.

The curved cover unit 100 includes a curved cover member 110 formed as a curved surface. As one embodiment, the curved cover member 110 may be glass or may be a protective member that protects a display part, and various modifications thereof are possible.

FIG. 2 is an enlarged view of part A of FIG. 1, which is a partial perspective view illustrating a state in which a first bracket member and a first support member of the curved cover unit attachment/detachment apparatus according to an embodiment of the present invention are coupled, and FIG. 3 is a partial rear perspective view illustrating the state in which the first bracket member and the first support member of the curved cover unit attachment/detachment apparatus according to an embodiment of the present invention are coupled.

Referring to FIGS. 1 to 3, the first bracket unit 200 includes a first bracket member 230 provided on the curved cover member 110 and a first support member 210 detachably installed on the first bracket member 230.

The first support member 210 includes first fixing portions 212 for fixing at least one of the curved cover unit 100 or the first bracket member 230 and first support portions 214 detachably coupled to the curved panel unit 300. The first bracket member 230 may be fixed to the curved cover unit 100 in various forms, for example, may be fixed to the curved cover unit 100 through a fixing means such as double-sided tape or directly fixed to the curved cover unit 100.

The first fixing portions 212 are provided in the first support member 210. In the present embodiment, a case where the first fixing portions 212 are through holes formed to pass through the first support member 210 is described as an example, but embodiments of the present invention are not limited thereto and various modifications thereof are possible. The first support member 210 is fixed to at least one of the curved cover unit 100 or the first bracket member 230 by first fastening members 213 passing through the first fixing portions 212. The first fixing portion 212 may be provided at any position in the first support member 210 as long as the first support member 210 is able to be fixed to at least one of the curved cover unit 100 or the first bracket member 230).

The first support portion 214 allows the first support member 210 to be detachably coupled to the curved panel unit 300. In one embodiment, the first support portion 214 may be shaped like a groove that is open through one side as illustrated in FIG. 3 and formed in a way of being caught on a protrusion (not illustrated) protruding from the curved panel unit 300. As another embodiment, although not illustrated in the figures, the first support portion 214 may be formed as a through hole formed to pass through the first support member 210 and the first support member 210 may be detachably coupled to the curved panel unit 300 by a first support fastening member (not illustrated) such as a screw or screw member passing through the first support portion 214, and various modifications thereof are possible.

FIG. 4 is a view illustrating a free support unit of the curved cover unit attachment/detachment apparatus according to an embodiment of the present invention, and FIG. 5 is a view illustrating a free support coupling unit of the curved cover unit attachment/detachment apparatus according to an embodiment of the present invention.

Referring to FIGS. 1, 4, and 5, the curved cover unit attachment/detachment apparatus 10 according to an embodiment of the present invention further includes free support units 235 provided on the first bracket member 230 and free support coupling units 310 provided on the curved panel unit 300 and coupled to the free support units 235.

The free support unit 235 according to an embodiment of the present invention includes a body portion 236 provided on the first bracket member 230, a first extension portion 237 extending from the body portion 236 in a first direction away from the first bracket member 230, and a second extension portion 238 extending from the first extension portion 237 in a direction different from the first direction to be spaced apart from the body portion 236. In the present embodiment, a case where the free support unit 235 has a hook shape as illustrated in FIG. 4 will be described as an example. In the present embodiment, the first extension portion 237 extends outward from the body portion 236 and extends from the body portion 236 to be bent at 90 degrees in the direction away from the first bracket member 230. The second extension portion 238 extends from the first extension portion 237 to be bent at 90 degrees, and the free support coupling unit 310 is inserted between the second extension portion 238 and the body portion 236. A connection site between the body portion 236 and the first extension portion 237 and a connection site between the first extension portion 237 and the second extension portion 238 are formed as a curved surface to facilitate rotation from the inserted free support coupling unit 310.

In the present embodiment, the free support coupling unit 310 is formed to protrude from the curved panel unit 300. The free support unit 235 is inserted into the free support coupling unit 310 formed to protrude from the curved panel unit 300. It is desirable that a plurality of free support units 235 and free support coupling units 310 are provided so that the curved cover unit 100 is stably coupled to the curved panel unit 300.

FIG. 5 is a view illustrating the free support coupling unit of the curved cover unit attachment/detachment apparatus according to an embodiment of the present invention, FIG. 6 is a partial perspective view illustrating part B of FIG. 1 in a state in which the curved cover unit attachment/detachment apparatus according to an embodiment of the present invention is coupled, and FIG. 7 is a rear perspective view of FIG. 6.

Referring to FIGS. 1 and 5 to 7, the second bracket unit 400 includes a second support member 405 coupled to at least one of the curved cover unit 100 or the first bracket unit 200. The second support member 405 includes second support portions 410 for detachably fixing at least one of the curved cover unit 100 or the first bracket unit 200 and second fixing portions 420 fixedly coupled to the curved panel unit 300. In more detail, the second support member 405 is coupled to the curved cover unit 100 to be separable and fixedly coupled to the curved panel unit 300 when dismantled.

The second support member 405 is coupled to at least one of the curved cover unit 100 or the first bracket member 230 by the second support portions 410 and is separated from the curved cover unit 100 and the first bracket member 230 when dismantled. The second support member 405 is fixed to the curved cover unit 100 or the first bracket member 230 by second support fastening members 412 passing through the second support portion 410, and when the second support fastening members 412 are separated from the curved cover unit 100 or the first bracket member 230, the curved cover unit 100 and the first bracket member 230 may be separated from the second support member 405. Second fastening members 422 fix the second support member 405 to the curved panel unit 300 so that the second support member 405 is fixed to the curved panel unit 300 when separated. In the present embodiment, a case where the second support portions 410 and the second fixing portions 420 are through holes formed to pass through the second support member 405 is described as an example, but embodiments of the present invention are not limited thereto and various modifications thereof are possible. The second support member 405 is fixed to the curved panel unit 300 by the second fastening members 422 passing through the second fixing portions 420.

The second fixing portions 420 are provided in the second support member 405. As described above, in the present embodiment, a case where the second fixing portions 420 are through holes formed to pass through the second support member 405 is described as an example, but embodiments of the present invention are not limited thereto and various modifications thereof are possible. The second support member 405 is fixed to the curved panel unit 300 by the second fastening members 422 passing through the second fixing portions 420. The second fixing portion 420 may be provided at any position in the second support member 405 as long as the second support member 405 is able to be fixed to the curved panel unit 300.

FIG. 8 is a view illustrating a free support unit and a free support coupling unit according to an embodiment of the present invention.

For convenience of description, description of components having the same function as the free support unit and the free support coupling unit according to an embodiment of the present invention will be omitted.

Referring to FIG. 8, a free support unit 235 and a free support coupling unit 310 according to an embodiment of the present invention have the same configuration as those in an embodiment of the present invention. In the present embodiment, in a state in which the free support unit 235 and the free support coupling unit 310 are coupled, a fitting coupling unit 317 formed on a separate additional member (a reference numeral is not shown) is inserted into the free support coupling unit 310.

As still another embodiment, although not illustrated in a separate figure, a through hole may be formed in the place of the free support coupling unit 310 illustrated in FIG. 8 and the free support coupling unit 310) may be formed to protrude at a position of the fitting coupling unit so that coupling is performed in a manner where the free support coupling unit 310 is inserted into the through hole. In this case, the free support unit 235 may be fitted and coupled to the free support coupling unit 310 formed to protrude at the position of the fitting coupling unit in FIG. 8, and various modifications thereof are possible.

Hereinafter, a curved cover unit attachment and detachment method according to an embodiment of the present invention will be described with reference to the attached drawings.

FIG. 9 is a flowchart showing a curved cover unit attachment and detachment method according to an embodiment of the present invention.

Referring to FIGS. 1 to 9, the curved cover unit attachment and detachment method according to an embodiment of the present invention includes a first separation step S10 of separating a first bracket unit 200 and a curved panel unit 300, a second separation step S20 of separating a second bracket unit 400 and a curved cover unit 100, and a third separation step S30 of separating the curved cover unit 100 from the curved panel unit 300. In the present embodiment, a case where the second separation step S20 is performed after performing the first separation step S10 is described as an example, but embodiments of the present invention are not limited thereto and various modifications are possible such as simultaneously performing the first separation step S10 and the second separation step S20 or first performing the second separation step S20.

First, in the first separation step S10, the first bracket unit 200 is separated from the curved panel unit 300 in a state in which the first bracket unit 200 is fixed to the curved cover unit 100. In more detail, a first support member 210) is fixed to at least one of the curved cover unit 100 or the first bracket member 230), and the first support member 210 and the curved panel unit 300 are in a separable state.

Next, in the second separation step S20, the second bracket unit 400 is separated from the curved cover unit 100 in a state in which the second bracket unit 400 is fixed to the curved panel unit 300. In more detail, when a second support fastening member 412 is separated from the curved cover unit 100 or the first bracket member 230, the second support member 405 is released from being fixed to the curved cover unit 100 and the first bracket member 230, and at this time, the second support member 405 remains fixed to the curved panel unit 300 by the second fastening member 422.

After the first separation step S10 and the second separation step S20, the first bracket unit 200 is in a state of being fixed to the curved cover unit 100 and in a state of being separable from the curved panel unit 300, and contrary to the first bracket unit 200, the second bracket unit 400 is in a state of being separable from the curved cover unit 100 and in a state of being fixed to the curved panel unit 300.

In the third separation step S30, the curved cover unit 100 is separated from the curved panel unit 300. When the curved cover unit 100 is moved upward, the free support unit 235 is removed from the free support coupling unit 310. When the curved cover unit 100 continues to move upward, the first bracket unit 200 moves upward together with the curved cover unit 100 in the state of being fixed to the curved cover unit 100. In this case, since the second bracket unit 400 is fixed to the curved panel unit 300, only the curved cover unit 100 may be separated from the curved panel unit 300. In the present embodiment, a case where the curved cover unit 100 is separated by moving the curved cover unit 100 upward of the curved panel unit 300 is described as an example, but embodiments of the present invention are not limited thereto and various modifications thereof are possible.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements. The mention of a “unit” or a “module” does not preclude the use of more than one unit or module.

1. A curved cover unit attachment/detachment apparatus comprising:
a curved cover unit having a curved cover member formed as a curved surface:
a first bracket unit provided on the curved cover unit:
a curved panel unit coupled to the first bracket unit; and
a second bracket unit provided on the curved panel unit and coupled to at least one of the curved cover unit or the first bracket unit.

2. The curved cover unit attachment/detachment apparatus of claim 1, wherein the first bracket unit includes:
a first bracket member provided on the curved cover member; and
a first support member detachably installed on the first bracket member.

3. The curved cover unit attachment/detachment apparatus of claim 2, wherein the first support member includes:
a first fixing portion that fixes at least one of the curved cover unit or the first bracket member; and
a first support portion detachably coupled to the curved panel unit.

4. The curved cover unit attachment/detachment apparatus of claim 2, further comprising:
a free support unit provided on the first bracket member; and
a free support coupling unit which is provided on the curved panel unit and to which the free support unit is coupled.

5. The curved cover unit attachment/detachment apparatus of claim 4, wherein the free support unit includes:
a body portion provided on the first bracket member:
a first extension portion extending from the body portion in a first direction away from the first bracket member; and
a second extension portion extending from the first extension portion in a direction different from the first direction to be spaced apart from the body portion.

6. The curved cover unit attachment/detachment apparatus of claim 1, wherein the second bracket unit includes a second support member coupled to at least one of the curved cover unit or the first bracket unit.

7. The curved cover unit attachment/detachment apparatus of claim 6, wherein the second support member includes:
a second support portion that detachably fixes at least one of the curved cover unit or the first bracket unit; and
a second fixing portion fixedly coupled to the curved panel unit.

8. The curved cover unit attachment/detachment apparatus of claim 1, wherein the first bracket unit is fixed to the curved cover unit and separably coupled to the curved panel unit, and the second bracket unit is separably coupled to the curved cover unit and fixed to the curved panel unit.

9. A curved cover unit attachment and detachment method comprising:
a first separation step of separating a first bracket unit and a curved panel unit;
a second separation step of separating a second bracket unit and the curved cover unit; and
a third separation step of separating the curved cover unit from the curved panel unit.

10. The curved cover unit attachment and detachment method of claim 9, wherein the first separation step includes separating the first bracket unit from the curved panel unit in a state of fixing the first bracket unit to the curved cover unit.

11. The curved cover unit attachment and detachment method of claim 9, wherein the second separation step includes separating the second bracket unit from the curved cover unit in a state of fixing the second bracket unit to the curved panel unit.

12. The curved cover unit attachment and detachment method of claim 9, wherein the third separation step includes separating the curved cover unit by moving the curved cover unit to one side of the curved panel unit.
